(19) United States
(12) Patent Application Publication
(10) Pub. No.: US 2014/0021044 A1
(43) Pub. Date: Jan. 23, 2014

(54) Elastomer Bonded Rotary Sputtering Target

(71) Applicant: Thermal Conductive Bonding, Inc., San Jose, CA (US)

(72) Inventors: Wayne R. Simpson, San Jose, CA (US); Jaime Francisco Guerrero, San Jose, CA (US)

(21) Appl. No.: 14/035,745

(22) Filed: Sep. 24, 2013

Related U.S. Application Data
(63) Continuation-in-part of application No. 11/541,984, filed on Oct. 2, 2006, now abandoned.
(60) Provisional application No. 61/842,311, filed on Jul. 2, 2013.

(51) Int. Cl. C23C 14/34

(52) U.S. Cl. CPC C23C 14/3407
USPC 204/298.13; 204/298.12; 156/307.1

(57) ABSTRACT

A sputtering target assembly and a method for manufacturing are disclosed. The sputtering target assembly comprises a cylindrical sputtering target section having a length greater than approximately thirty-six inches and being comprised of one or more cylindrical ring targets; a cylindrical backing tube positioned inside of the cylindrical sputtering target; at least one electrically conductive shim that makes an electrical connection between the cylindrical sputtering target and the cylindrical backing tube; and an attachment layer comprised of an elastomer positioned between the cylindrical sputtering target and the cylindrical backing tube for attaching the cylindrical sputtering target to the cylindrical backing tube.

This application claims the benefit of U.S. provisional application 61/842,311, filed Jul. 2, 2013, which is incorporated herein by reference. This application is a continuation-in-part of U.S. patent application Ser. No. 11/541,984, filed Oct. 2, 2006, which is incorporated herein by reference, and which claimed the benefit of U.S. provisional application 60/723,413, filed Oct. 3, 2005.

### BACKGROUND OF THE INVENTION

Sputtering is a major vacuum deposition technique used to deposit a thin film of a target material on a substrate. Many materials are capable of being sputtered and typical target materials include elemental metals (such as copper, gold, tungsten, molybdenum and aluminum etc.), alloys (such as aluminum-copper alloy, aluminum-neodymium and titanium-tungsten alloy, etc.), and compounds (such as silicon dioxide and titanium nitride, etc.). Typical substrates on which the target material is deposited include items such semiconductor devices, compact discs (CD), hard disks for use in magnetic disk drives, and optical devices such as flat panel displays.

A typical sputtering apparatus comprises a vacuum chamber inside of which are positioned the target and the substrate. The target is electrically configured to be an electrode with a large ion flux. The chamber is filled with an inert gas which ionizes when power is supplied to the target/electrode. The positively charged inert gas ions collide with the target causing atomic sized particles to be ejected from the target. The particles are then deposited on the surface of the substrate as a thin film.

Because of this electrical configuration, the target can become very hot and needs to be cooled. In a typical sputtering apparatus, the cooling is provided by a water-cooled backing member to which the target is attached by an attachment layer. In some sputtering systems, a rectangular target and backing plate are used, while in other systems, the target and backing plate are cylindrical in shape.

A trend in the manufacturing of flat panel displays and other devices is to manufacture many devices on a very large substrate, much like smaller semiconductor devices are manufactured on wafers. For example, flat panel display manufacturers would like to be able to process square or rectangular flat panel display substrates having surface areas on the order of approximately 1200 square inches (7742 square centimeters) to 6000 square inches (38,700 square centimeters) or more. Some of these large substrates are currently being processed using large rectangular sputtering targets that are indium bonded to a backing plate. However, cylindrical sputtering targets long enough for use with substrates having surface areas on the order of approximately 1200 square inches or more present special bonding considerations and problems.

The use of cylindrical or rotary sputtering targets is described in U.S. patent application Ser. No. 11/541,984, Publication No. 2007/0074969 A1 and the use of elastomers for bonding sputtering targets to a flat backing member is described in U.S. patent application Ser. No. 11/147,105, Publication No. 2006/0272941 A1, published Dec. 7, 2006, which is incorporated herein by reference.

### SUMMARY OF THE PRESENT INVENTION

Briefly, the present invention comprises a cylindrical sputtering target assembly comprised of a cylindrical sputtering target section having a length greater than approximately thirty-six inches and being comprised of one or more cylindrical ring targets. A cylindrical backing tube is positioned inside of the cylindrical sputtering target. An attachment layer comprised of an elastomer, such as a silicone elastomer, is positioned between the cylindrical sputtering target and the cylindrical backing tube for attaching the cylindrical sputtering target to the cylindrical backing tube, with the attachment layer being sufficiently strong to keep the cylindrical sputtering target attached to the cylindrical backing tube during a sputtering process without the use of additional mechanical attachment means. At least one electrically conductive shim that makes an electrical connection between the cylindrical sputtering target and the cylindrical backing tube is positioned in the attachment layer between the cylindrical sputtering target and the cylindrical backing tube.

### BRIEF DESCRIPTION OF THE SEVERAL VIEWS OF THE DRAWINGS

FIG. 1 is an isometric view of a cylindrical sputtering target assembly;

FIG. 2 is a side view of a cylindrical sputtering target assembly;

FIG. 3 is a cross-sectional view taken along the line 3-3 in FIG. 2 according to the present invention;

FIG. 4 is an isometric view of an electrically conductive shim according to the present invention;

FIG. 5 is a top view of a metal sheet used to make an electrically conductive shim;

FIG. 6 is an isometric view of part of a cylindrical sputtering target assembly according to the present invention; and

FIG. 7 is an isometric view of a backing tube in a vertical orientation.

### DETAILED DESCRIPTION OF THE INVENTION

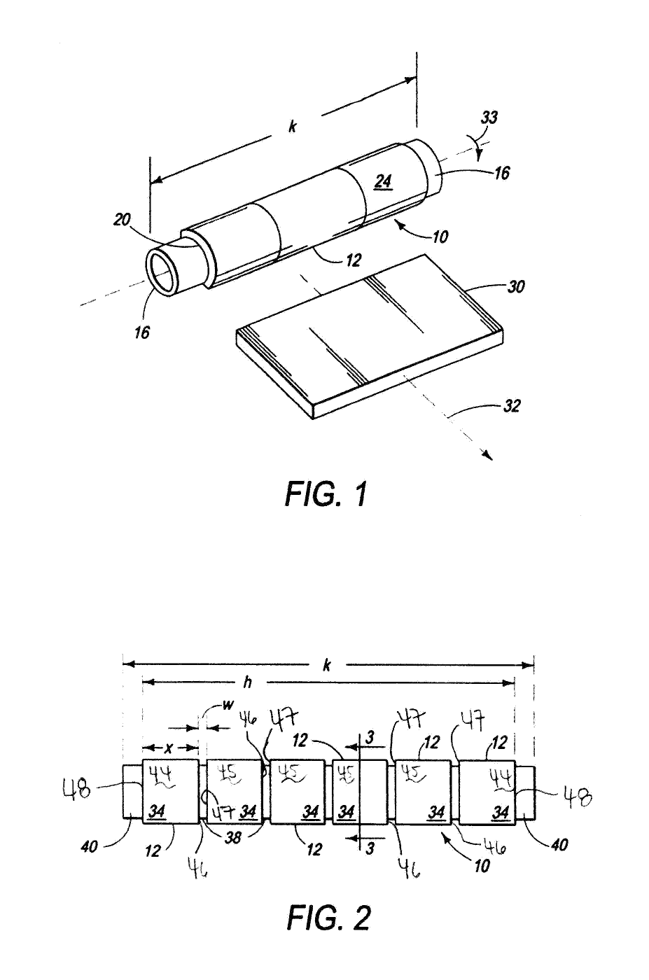

FIG. 1 illustrates a cylindrical sputtering assembly 10 that comprises a cylindrical sputtering target 12, a cylindrical backing tube 16 and an attachment layer 20. The cylindrical sputtering target has a sputtering face 24 from which the material to be sputtered on a substrate 30 is ejected. The cylindrical sputtering target 12 can be one continuous piece of material, or it can be comprised of two or more separate pieces. The sputtering target 12 is cooled by water running through the lumen (hollow passage) inside of the backing tube 16.

A magnetron (an assembly of magnets) can also be positioned in the lumen of the backing tube 16 for generating magnetic flux that attracts ions in the plasma that cause target material to be sputtered onto the substrate 30, for example as a thin film. Generally, the substrate 30 is moved laterally under the cylindrical sputtering assembly 10 in the direction of the arrow 32. The cylindrical sputtering assembly 10 can be rotated in the direction of the arrow 33 so that material from the entire surface area of the sputtering face 24 is used in the sputtering process.

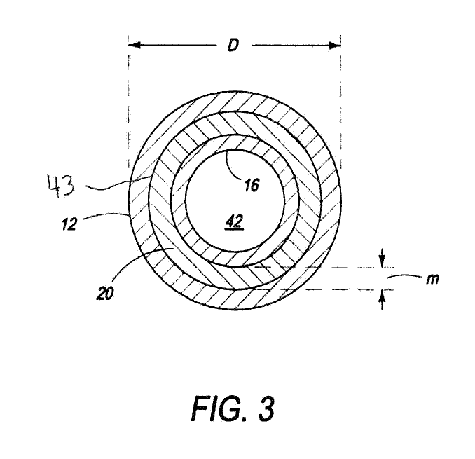

In the present invention, the cylindrical sputtering target assembly 10 comprises the cylindrical sputtering target 12, the cylindrical backing tube 16 and the attachment layer 20. The sputtering target 12 includes the sputtering surface 24 which is a surface from which the material to be sputtered on the substrate can be ejected when the sputtering process begins. In the present invention, the length “h” of the cylindrical sputtering target 12 (shown in FIG. 2) is preferably greater than thirty-six inches, and more preferably is greater than forty inches (101.6 cm), and most preferably is in the range of forty inches (101.6 cm) to one hundred and thirty inches (330.2 cm) or greater. Additionally, the cylindrical sputtering target 12 has an outer diameter “D” (shown in FIG. 3), but the length “h” is a more important parameter to the present invention than is the diameter “D.” For reference purposes the outer diameter “D” is usually greater than about five and one half inches (5.5 in), and more preferably is in the range of 5.5 to 9.45 inches (14 to 24 cm).

FIG. 2 illustrates that the sputtering surface 24 of the cylindrical sputtering target 12 is comprised of one or more individual cylindrical ring targets 34. When two or more ring targets 34 are used, a gap 38 exists between each pair of adjacent ring targets 34. The gap 38 has a width “w” which is on the order of approximately 0.02 inch (0.5 mm). As used herein, the length “h” of the cylindrical sputtering target 12 refers to the total length of the sputtering surface 24 in a single cylindrical sputtering assembly 10, regardless of whether the sputtering target is comprised of one piece of material or more than one piece. In other words, the length “h” includes the total of all of the lengths “x” of the individual cylindrical ring targets 34.

In FIG. 2, the length “h” is shown as including the widths “w” of the gaps 38, since the sum of the widths “w” is very small. This approximation is acceptable because the sum of the widths “w” is much smaller than the length “h.” Notwithstanding this acceptable approximation, the length “h” of the cylindrical sputtering target 12 refers to the total length of the sputtering surface 24. The length “h” is less than the length “k” of the assembly 10 because an exposed section 40 of the backing tube 16 extends beyond the last cylindrical ring target 34 on each end of the cylindrical sputtering assembly 10.

FIG. 2 illustrates that there are two sets of ring targets 34. The first set 44 contains the two ring targets 34 (called the end ring targets or end targets) that are positioned adjacent to the exposed section 40 at each end of the backing tube 16. The second set 45 includes all of the ring targets 34 (called the middle ring targets or middle targets) that are positioned between the two end ring targets. When two of the ring targets 34 are adjacent to each other, they have a set of opposing ends referred to as a first end 46 and a second end 47. The first end 46 on one ring target faces (or opposes) the second end 47 on the second ring target. Additionally, the two end ring targets in the first set 44 each have an end 48 adjacent to the exposed section 40.

Each of the individual cylindrical ring targets 34 (also called cylindrical sputtering target sections 34) is a cylindrical piece of material comprised of a sputtering target material. The individual cylindrical ring targets 34 are hollow in the middle so as to accommodate the backing tube 16 and attachment layer 20 (shown in FIG. 3). The length “x” of the individual cylindrical ring targets 34 can be any length, but in a representative example the length “x” is approximately eight inches (20.32 cm). Additionally, the length “x” can be different for individual cylindrical ring targets 34 within a given cylindrical sputtering target 12.

By using a plurality of individual cylindrical ring targets 34 having relatively short lengths “x”, it is easier to build a long cylindrical sputtering target 12 having the length “h” greater than thirty-six inches. This is particularly true for certain sputtering materials like ceramic materials, where it is difficult (or not possible) to make a single cylindrical ring target 34 where the length “x” is greater than thirty-six inches. However, with other sputtering materials, such as metals, a single cylindrical ring target 34 having the length “x” greater than thirty-six inches could be used in the present invention.

The cylindrical sputtering target 12 (and hence the individual cylindrical ring targets 34) can be comprised of many materials. Typical sputtering target materials include elemental materials (such as silver, silicon, copper, gold, tungsten, molybdenum and aluminum etc.), alloys (such as aluminum-copper alloy, aluminum-neodymium, cadmium-tin, indium-tin-oxide (ITO), and titanium-tungsten alloy, etc.), and compounds (such as silicon dioxide, glass, silicon carbide, aluminum doped zinc oxide (AZO), ceramic materials and titanium nitride, etc.).

FIG. 3 illustrates that the attachment layer 20 is positioned between the cylindrical sputtering target 12 and the backing tube 16, and that the attachment layer 20 has a width “m.” The backing tube 16 is a long hollow cylindrical tube that is strong enough to mechanically support the cylindrical sputtering target 12. The backing tube 16 includes a lumen 42 through which water or some other fluid can flow to act as a coolant for the cylindrical sputtering target 12. In a preferred embodiment, the backing tube 16 comprises stainless steel or titanium tube, but other materials such as aluminum or aluminum alloys, and copper or copper alloys can be used. The cylindrical sputtering target 12 (and each cylindrical ring target 34) has an inside surface 43 that abuts the attachment layer 20 in FIG. 3.

In a preferred embodiment, the attachment layer 20 attaches the cylindrical sputtering target 12 to the cylindrical backing tube 16 and comprises an elastomer. When the attachment layer 20 comprises an elastomer, the width “m” is preferably in the range of approximately 0.020 to 0.040 inches (0.51 to 1.0 mm), although other widths can be used.

The elastomer may comprise a silicone elastomer, including a poly(dimethylsiloxane) elastomer, such as Sylgard® 184 brand silicone elastomer sold by Dow Corning. Other types of suitable elastomers can be used as the attachment layer 20 such as polymers compatible with a vacuum environment. Generally, the elastomer should be able to withstand temperatures above 50° C. while maintaining a suitably strong bond between the sputtering target and the backing plate and adequately transferring heat from the sputtering target to the backing plate. Specific types of elastomers that can be used include polyimide, polyketone, polyetherketone, polyether sulfone, polyethylene terephthalate, and fluoroethylene propylene (FEP) copolymers. Flexible epoxy or rubber can also be used. Other silicone elastomers that can be used include the products marketed as General Electric RTV 31 and General Electric RTV 615 brand silicone elastomers.

FIG. 4 illustrates a conductive shim 50 that is used to ensure that a good electrical connection exists between the backing tube 16 and the cylindrical sputtering target 12 (i.e. the ring targets 34). In a preferred embodiment, the shim 50 is a member comprised of an electrically conductive material that functions to form an electrical connection between the backing tube and the sputtering target. For example, the shim 50 may comprise a thin piece of metal, such as titanium, having a thickness “t” and a width “M” that has been bent to have a “W” shape comprised of four sections 52. In other embodiments, other electrically conductive materials could be used and the shim 50 could have other shapes and dimensions.

In a preferred embodiment, two types of shims are used: large shims and small shims. In the large shims, the width “M” is larger than in the small shims. The large shims are placed underneath the first end 46 and the second end 47 of two adjacent ring targets, while the small shims are placed underneath the ends 48 of the first set 44 of ring targets that are at the end of the sputtering surface 24.

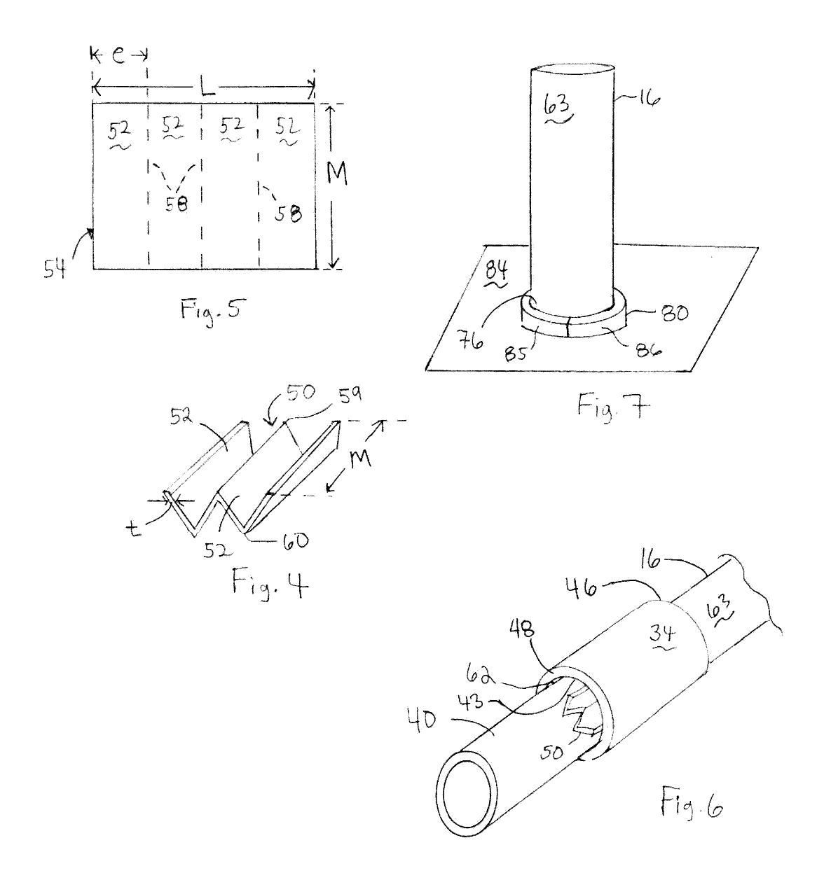

A preferred method of making the W-shaped shim 50 is to fold/bend a rectangular piece of metal 54 along the lines 58 illustrated in FIG. 5. The piece of metal 54 has a length “L” and the width “M” (shown in FIGS. 4 and 5). Folding the piece of metal 54 along the lines 58 creates the four sections 52 having a dimension “e.” After folding, the shim has a plurality of high points 59 and low points 60 (shown in FIG. 4) along the edges of the sections 52. In a preferred embodiment, the shim 50 comprises titanium, the thickness “t” is approximately 0.005 inches, the length “L” is approximately 2.0 inches, the dimension “e” is approximately 0.5 inches, and the width “M” is either 1.5 inches or 3.0 inches.

During a direct current (DC) sputtering process, the sputtering target assembly 10 functions as the negative electrode (cathode) in a sputtering chamber. Generally, this is accomplished by connecting the backing tube 16 to the negative terminal of a DC power supply to apply a voltage (e.g. in the range of −2 to −5 kV) to the backing tube 16. To ensure that the entire sputtering surface 24 is held at a uniform voltage, it is desirable to have a good electrical connection between the backing tube 16 and the individual ring targets 34. This is accomplished by inserting one or more of the conductive shims 50 under the ends of the ring targets 34, so that the shim 50 provides an electrical connection between the backing tube 16 and one or more of the ring targets 34 (i.e. the cylindrical sputtering target 12).

FIG. 6 illustrates one of the shims 50 inserted underneath the ring target 34 in a space 62 between the backing tube 16 and the ring target 34 when no attachment layer 20 is present. Generally, the shim 50 will flatten out somewhat when it is inserted underneath the ring target 34, but the high points 59 and low points 60 in the W-shape of the shim 50 cause contact between the shim 50, the backing tube 16 and the ring target 34. Stated differently, the shim 50 contacts the inside surface 43 of the ring target 34 and an outside surface 63 of the backing tube 16.

In a preferred embodiment, three of the small shims 50 are placed around the end 48 of the ring target 34 at approximately equal intervals. The end 48 is adjacent to the exposed section 40 of the backing tube 16 (also discussed in FIG. 2). Three of the large shims 50 are placed around the first end 46 of the ring target 34 at approximately equal intervals. The first end 46 is at the opposite end of the ring target 34 from the end 48.

FIG. 7 illustrates the backing tube 16 positioned for application of the elastomer. Before the elastomer is applied, the backing tube 16 is positioned in the vertical orientation illustrated in FIG. 7, with a first end 76 of the backing tube 16 inserted into a fixture 80. The fixture 80 is attached to a flat surface 84 so that the fixture 80 holds the backing tube 16 in the vertical position. The fixture 80 also sets the length of the exposed section 40 because the part of the backing tube 16 that slides into the fixture 80 will not get covered with elastomer and thus becomes the exposed section 40. Preferably, the fixture 80 is comprised of a first piece 85 and a second piece 86, both comprised of aluminum.

The outside surface of the backing tube 16 is then covered with an even layer of elastomer. The layer of elastomer is preferably approximately 0.25 inches thick, although other thicknesses can be used. Next, with one of the first set 44 of the ring targets 34 resting horizontally, the inside surface 43 of the ring target 34 is covered with an even layer of elastomer. Generally, the layer of elastomer is preferably approximately 0.25 inches thick on the inside surface 43, although other thicknesses can be used. With the backing tube 16 still in the vertical position (i.e. upright), the ring target 34 (i.e. one of the first set 44 end ring targets) is slid down over the backing tube 16 until an end of the ring target 34 is about 3.5 inches away from the fixture 80. Three of the small shims are positioned around the end 48 of the ring target 34 (see FIG. 6) by pushing the shims underneath the ring target 34. Then the ring target 34 is pushed slowly downward until the end 48 is resting on the fixture 80. Three of the large shims are positioned around the first end 46 of the ring target 34 by pushing the shims underneath the ring target 34 until approximately half of each shim is underneath the first end 46 and half of each shim is still exposed.

The inside surface of the next ring target 34 (i.e. one of the second set 45 end ring targets) is covered with an even layer of elastomer and the ring targets 34 is slid down over the backing tube 16, and over the exposed half of the large shims 50 that are already in position, until an end of the ring target 34 is resting against the other ring target 34. Additional ring targets 34 and shims are added in a similar manner until all of the ring targets 34 are positioned on the backing tube 16. Three of the small shims are positioned underneath the end 48 of the top ring target 34 (i.e. the top first set 44 end ring target) by pushing the shims underneath the ring target 34. Example one, below, describes one way of preparing the cylindrical sputtering assembly 10 when the attachment layer 20 comprises an elastomer.

### Example 1

The steps involved in the method are:

1. Prepare the backing tube 16 by blasting at approximately 80 psi with a material such as silicon carbide to clean and smooth the surface 63 of the backing tube 16. Generally, only the area on the backing tube that will be underneath the ring targets 34 needs to be blasted. Areas that do not need to be blasted, such as the exposed section 40, can be protected with tape or by other protective materials or methods.

2. Protect the outside surface of the ring targets 34, such as by covering the outside surface with polyester (PET)/silicone adhesive tape (i.e. the sputtering surface 24 is covered with tape).

3. For each two ring targets 34 that will be adjacent to each other on the backing tube, protect one of the adjacent ends (e.g. the first end 46), such as by covering it with Kapton™ brand polyimide tape, to prevent elastomer from adhering to that end.

4. Similarly, protect the two ends 48 (i.e. the ends of the two ring targets 34 that will be adjacent to the exposed sections 40), such as by covering the ends with Kapton™ brand polyimide tape to prevent elastomer from adhering to that ends.

5. Prepare six small titanium shims (0.005 inches thick by two inches long by 1.5 inches wide) for centering around the end ring targets 34. Fold each shim 50 along the two inch length so that there are three folds and four 0.5 inch faces, to yield a “W” shaped shim.

6. Prepare three of the large titanium shims (0.005 inches thick by two inches long by three inches wide) for centering around the middle ring targets 34 (preferably three large shims per each middle ring target). Fold each shim along the two inch length so that there are three folds and four 0.5 inch faces, to yield a “W” shaped shim. The number of shims prepared in steps 5 and 6 assumes that only two ring targets 34 are being used. If more of the middle ring targets 34 are used (i.e. more second set 45 ring targets), then more large shims should be prepared.

7. Prepare the fixture 80 by connecting the two pieces 85 and 86, such as by taping the two pieces together with Kapton™ brand polyimide tape. The tape also helps keep the end target 34 from being bonded to the fixture 80 with elastomer.

8. As a dry run to check the fit of the various components, slide the ring targets 34 onto the backing tube 16 and slide the shims 50 into place underneath the ring targets 34. After the correct fit has been checked, carefully take apart the sputtering assembly.

9. Clean the ring targets 34 and backing tube 16, such as by wiping with acetone. Then apply a primer to the ring targets 34 and backing tube 16 (e.g. Dow Corning P5200 Clear brand primer may be used).

10. For the ring targets 34 prepared in step 3, prepare the end not covered with Kapton™ brand polyimide tape (i.e. the second ends 47) by attaching a Teflon® brand fluoropolymer (polytetrafluoroethylene or PTFE) ring around the end. For example, the PTFE ring can be a 0.010 inch thick piece of PTFE attached to the second end 47 using double-sided tape.

11. Prepare the elastomer for use. For Dow 184 elastomer, the manufacturer's preparation instructions can be used. In a preferred embodiment, the following modified preparation of the elastomer is used:

a. In a preferred embodiment, the elastomer comprises a poly(dimethylsiloxane) elastomer, such as Sylgard® 184 brand silicone elastomer. In such an embodiment, the two-part poly(dimethylsiloxane) elastomer is mixed according to the manufacturer's instructions using a 10:1 ratio of the base to the curing agent. A conductive powder may be added to increase the electrical conductivity of the elastomer. For example, in some embodiments, graphite powder is added to the mixture (e.g. approximately 20% by weight of graphite relative to the base). Of course other amounts may be used depending on the specific materials and applications involved. The elastomer is degassed before using.

12. Stand the backing tube 16 in the vertical position (i.e. upright), such as by using the bottom fixture 80. Cover the outside surface 88 of the backing tube 16 with an even layer of elastomer, approximately 0.25 inches thick, preferably using gloved hands (latex gloves) to apply and spread the elastomer.

13. With the first end ring target 34 resting horizontally (i.e. one of the first set 44 targets), cover the inside surface 43 of the ring target with an even layer of elastomer, approximately 0.25 inches thick, preferably using gloved hands (latex gloves) to apply and spread the elastomer.

14. With the backing tube 16 still in the vertical position (i.e. upright), slide the first end ring target 34 down over the backing tube and push three of the small shims underneath an end of the first end ring target 34 before that end hits the fixture. Then slide the first end ring target 34 down the rest of the way until the end 48 of the first end ring target 34 is resting on the fixture. Do not let the first end ring target 34 touch the backing tube as it is slid into position.

15. Position three large shims in the gap between the backing tube and the first end ring targets 34 at equal distances around the circumference of the first end ring targets 34.

16. Add some elastomer inside the bond by using a thin tool, such as a feeler gauge, to push elastomer down into the gap between the backing tube and the first end target section.

17. With the second end target section resting horizontally (i.e. one of the second set 45 targets), cover the inside surface 43 of the target section with an even layer of elastomer, approximately 0.25 inches thick, preferably using gloved hands (latex gloves) to apply and spread the elastomer.

18. With the backing tube still in the vertical position, slide the second end target section down over the backing tube, and over the three large shims, until an end of the second end target section is resting against an end of the first end target section. Do not let the second end target section touch the backing tube as it is slid into position.

19. Position three small shims between the backing tube and the end of the second end target section (i.e. underneath the end 48 of the other first set 44 target) at equal distances around the circumference of the second end target section.

20. Add some elastomer inside the bond by using a thin tool, such as a feeler gauge, to push elastomer down into the gap between the backing tube and the second end target section.

21. Place a top ring fixture (similar to the fixture 80) over the end of the second end target section. Cover each gap between adjacent ring targets 34 and between each ring target 34 and the fixture 80 with tape, such as a 0.5 inch wide piece of Kapton™ brand polyimide tape. Then place a 100 pound load on the top ring fixture. Cover the assembly with aluminum foil and cure the assembly at 50° C. for twelve hours.

22. After curing, allow the assembly to cool down to room temperature before removing the cylindrical sputtering assembly 10 from the fixture 80.

23. After the assembly 10 has cooled to room temperature, remove it from the fixture 80 and remove all of the tape from the assembly 10. Remove the Teflon® brand fluoropolymer rings and the Kapton™ brand polyimide tape from the gaps and cut away any excess elastomer. Clean the gaps thoroughly with alcohol and dry the assembly 10 with nitrogen. Remove any other tape and remove all tape stains and oxidation from the targets 34, such as by using a scuff pad. A die grinder may be used if needed. Clean the inside diameter of the backing tube 16, such as with a scuff pad. Finally, wipe the entire target assembly with alcohol and a towel, and dry the assembly 10 with nitrogen.

The use of elastomers as the bonding layer 20 is preferred in at least three types of sputtering situations. First, the use of an elastomer bonding layer is preferred where a hot sputtering process will be employed. A hot sputtering process means that the cylindrical sputtering target 12 is intentionally allowed to heat up to a relatively high temperature because the higher temperature improves the result of the physical sputtering process.

With hot sputtering, elastomer bonded sputtering assemblies are preferred because the elastomer bonding layer doesn't crack as easily when cooled, compared to other bonding materials such as indium. The use of elastomers as the bonding layer 20 has been found to be especially useful in hot sputtering processes where the sputtering targets 34 are comprised of transparent conductive oxide (TCO) materials which are known to sputter better hot. Transparent conductive oxides are doped metal oxides used in optoelectronic devices such as flat panel displays and photovoltaic devices, and include materials such as tin doped indium oxide (ITO), aluminum doped zinc oxide (AZO) and indium doped cadmium oxide.

Second, the use of an elastomer bonding layer is preferred where the ring targets 34 are comprised of a material that tends to form an alloy with indium. In such cases, if indium is used as the bonding layer 20, the bonding layer and the sputtering material in the ring targets form and alloy that reduces the bonding strength of the bonding layer 20. The alloying also makes it more difficult to reuse the assembly 10 after the sputtering process is finished. Cadmium-tin and cadmium-zinc ring targets are examples of sputtering target materials that form alloys with indium and therefore work better with an elastomer bonding layer 20.

Third, the use of an elastomer bonding layer is preferred in other situations where the mechanical properties of the elastomer are desired (e.g. greater elasticity). For example, an elastomers bonding layer may be desired where the sputtering targets 34 are comprised of materials such as silicon, glass or ceramics.

A problem with using elastomers as the bonding layer 20 is that the elastomer may not have enough electrical conductivity to maintain the sputtering surface 24 at the desired voltage. The desired voltage is applied to the backing tube 16, but the bonding layer 20 might not be sufficiently conductive to maintain the sputtering surface 24 (and the sputtering target 12) at the voltage applied to the backing tube. This problem can be partly overcome by adding an electrically conductive component to the elastomer, such as graphite or metal powder, when the elastomer is being prepared to increase the conductivity of the bonding layer 20.

The use of the shims 50 is another solution to this problem. The shims 50 are comprised of an electrically conductive material, such as a metal. The shape of the shims 50 is chosen so that each shim acts as an electrical connection between the backing tube 16 and at least one of the ring targets 34. Specifically, the high points 59 in the W-shape of the shim make contact with the ring target while the low points 60 in the W-shape make contact with the backing tube. The elastomer in the bonding layer 20 surrounds each shim 50, but the spring force in the W-shape of the shim is sufficiently strong so that the high and low points cut through the elastomer and make electrical contact between the backing tube 16 and the ring targets 34 (i.e. the cylindrical sputtering target 12).

In a preferred embodiment, the sputtering target assembly 10 comprises the cylindrical sputtering target 12 having a length greater than approximately thirty-six inches and being comprised of one or more of the cylindrical ring targets 34; the cylindrical backing tube 16 positioned inside of the cylindrical sputtering target; at least one of the electrically conductive shims 50 that makes an electrical connection between the cylindrical sputtering target 12 and the backing tube 16; and an attachment layer 20 comprised of an elastomer positioned between the cylindrical sputtering target and the cylindrical backing tube for attaching the cylindrical sputtering target to the cylindrical backing tube where the attachment layer is sufficiently strong to keep the cylindrical sputtering target attached to the cylindrical backing tube during a sputtering process without the use of other mechanical attachment means such as bolts, restraining rings or interlocking parts.

In a preferred embodiment, the cylindrical sputtering target is comprised of a transparent conductive oxide material, such as indium-tin-oxide (ITO) or aluminum doped zinc oxide (AZO) and the elastomer comprises a silicone elastomer.

In a preferred embodiment, the sputtering target assembly 10 is assembled by orienting the backing tube 16 in a vertical position; applying a first layer of the elastomer to an outside surface of the backing tube; applying a second layer of the elastomer to an inside surface of a cylindrical ring target; bringing the cylindrical backing tube and the cylindrical ring target together so that the outside surface of the cylindrical backing tube and the inside surface of the cylindrical ring target are adjacent to each other with at least some of the first layer of elastomer being in contact with the second layer of elastomer; positioning at least one of the electrically conductive shims so that it makes electrical contact with the cylindrical backing tube and the cylindrical ring target; repeating steps c, d and e, if necessary, until a cylindrical sputtering surface 24 is formed around the cylindrical backing tube having a length greater than thirty-six inches; and curing the elastomer, thereby forming the attachment layer 20 that is sufficiently strong to keep the one or more cylindrical ring targets attached to the cylindrical backing tube during a sputtering process.

Although the present invention has been described in terms of the presently preferred embodiments, it is to be understood that such disclosure is not to be interpreted as limiting. Various alterations and modifications will no doubt become apparent to those skilled in the art after having read the above disclosure. Accordingly, it is intended that the appended claims be interpreted as covering all alterations and modifications as fall within the true scope of the invention.

We claim:

1. A sputtering target assembly comprised of:
a cylindrical sputtering target having a length greater than approximately thirty-six inches and being comprised of one or more cylindrical ring targets;
a cylindrical backing tube positioned inside of the cylindrical sputtering target;
at least one electrically conductive shim that makes an electrical connection between the cylindrical sputtering target and the cylindrical backing tube; and
an attachment layer comprised of an elastomer positioned between the cylindrical sputtering target and the cylindrical backing tube for attaching the cylindrical sputtering target to the cylindrical backing tube, and where the attachment layer is sufficiently strong to keep the cylindrical sputtering target attached to the cylindrical backing tube during a sputtering process.

2. The sputtering target assembly of claim 1 wherein the length of the cylindrical sputtering target is greater than forty inches.

3. The sputtering target assembly of claim 1 wherein the cylindrical sputtering target is comprised of a transparent conductive oxide material.

4. The sputtering target assembly of claim 3 wherein the transparent conductive oxide material is selected from the group consisting of indium-tin-oxide (ITO) and aluminum doped zinc oxide (AZO).

5. The sputtering target assembly of claim 1 wherein the elastomer comprises a silicone elastomer.

6. The sputtering target assembly of claim 5 wherein the silicone elastomer comprises a poly(dimethylsiloxane) elastomer.

7. The sputtering target assembly of claim 1 wherein the electrically conductive shim is comprised of titanium.

8. The sputtering target assembly of claim 1 wherein the electrically conductive shim has at least one high point and a least one low point.

9. The sputtering target assembly of claim 1 wherein the electrically conductive shim has a “W” shape.

10. The sputtering target assembly of claim 1 wherein the cylindrical sputtering target is comprised of two or more cylindrical ring targets.

11. A method comprising:
a) orienting a backing tube in a vertical position;
b) applying a first layer of an elastomer to an outside surface of the backing tube;
c) applying a second layer of the elastomer to an inside surface of a cylindrical ring target;
d) bringing the cylindrical backing tube and the cylindrical ring target together so that the outside surface of the cylindrical backing tube and the inside surface of the cylindrical ring target are adjacent to each other with at least some of the first layer of elastomer being in contact with the second layer of elastomer;
e) positioning at least one electrically conductive shim so that it makes electrical contact with the cylindrical backing tube and the cylindrical ring target;
f) repeating steps c, d and e, if necessary, until a cylindrical sputtering surface is formed around the cylindrical backing tube having a length greater than thirty-six inches;
g) curing the elastomer, thereby forming an attachment layer that is sufficiently strong to keep the one or more cylindrical ring targets attached to the cylindrical backing tube during a sputtering process.

12. The method of claim 11 wherein step f results in a cylindrical sputtering surface being formed having a length greater than forty inches.
